(19) United States
(12) Patent Application Publication
(10) Pub. No.: US 2022/0112903 A1
(43) Pub. Date: Apr. 14, 2022

(54) AIR COMPRESSOR

(71) Applicant: INTRADIN (SHANGHAI) MACHINERY CO., LTD., SHANGHAI (CN)

(72) Inventor: Junliang WANG, Shanghai (CN)

(21) Appl. No.: 17/516,939

(22) Filed: Nov. 2, 2021

(30) Foreign Application Priority Data
Nov. 10, 2020 (CN) 202011246972.0

(51) Int. Cl. F04D 29/58; F04D 25/06; F04D 29/40

(52) U.S. Cl. CPC F04D 29/5813; F04D 29/584; F04D 29/403; F04D 25/068

(57) ABSTRACT

An air compressor includes a controller, a pump and an air storage tank. The pump is in communication with the air storage tank. A first air inlet and a first air outlet are provided on the pump. The pump is configured to pump an external air into the air storage tank. The controller is provided at the first air inlet of the pump, and is electrically connected with the pump. The controller is configured to control the operation of the pump. The external air is in contact with the controller, and enters the pump through the first air inlet and then flows out of the pump through the first air outlet, so as to realize a heat dissipation of the pump and the controller.

### CROSS-REFERENCE TO RELATED APPLICATIONS

This application claims the benefit of priority from Chinese Patent Application No. 202011246972.0, filed on Nov. 10, 2020. The content of the aforementioned application, including any intervening amendments thereto, is incorporated herein by reference in its entirety.

### TECHNICAL FIELD

The present application relates to air compression, and more particularly to an air compressor.

### BACKGROUND

In the prior art, the operation of the air compressor will cause a temperature rise in the controller. Considering that the controller cannot work under the condition of high temperature for a long time, it is necessary to immediately turn off the controller when the temperature exceeds a preset value, and cool the controller till the temperature is restored to be lower than the preset value.

### SUMMARY

In view of the defects in the prior art, an object of this disclosure is to provide an air compressor, which is capable of cooling the controller during the operation.

Technical solutions of the disclosure are described as follows.

The present disclosure provides an air compressor, comprising:

an air storage tank;

a pump; and

a controller;

wherein the pump is in communication with the air storage tank; a first air inlet and a first air outlet are provided on the pump; and the pump is configured to pump an external air into the air storage tank; and

the controller is provided at the first air inlet of the pump, and is electrically connected with the pump; the controller is configured to control an operation of the pump; the external air is in contact with the controller, and enters the pump through the first air inlet and then flows out of the pump through the first air outlet, so as to realize a heat dissipation of the pump and the controller.

In an embodiment, the pump comprises a first housing, a driving assembly and a push rod; the push rod is arranged in the first housing, and divides an interior of the first housing into a first accommodating cavity and a second accommodating cavity; the driving assembly is arranged in the first accommodating cavity, and is connected with the push rod; the controller is electrically connected with the driving assembly; the controller is configured to control the driving assembly to drive the push rod to move along a first direction or along a second direction opposite to the first direction; a side wall of the first housing is provided with the first air inlet and the first air outlet, and the first air inlet and the first air outlet are in communication with the first accommodating cavity; the external air is in contact with the controller and passes through the first air inlet to enter the first accommodating cavity, and then flows out of the first accommodating cavity through the first air outlet, so as to realize heat dissipation of the driving assembly and the controller; the first housing is further provided with a second air inlet and a second air outlet; the second air inlet is in communication with the second accommodating cavity; the second air outlet is in communication with the second accommodating cavity and the air storage tank; when the driving assembly drives the push rod to move along the first direction, the second accommodating cavity is expanded, and an air pressure in the second accommodating cavity is lowered, so that the external air is drawn to the second accommodating cavity through the second air inlet; when the driving assembly drives the push rod to move along the second direction, the second accommodating cavity is shrunk, and the air pressure in the second accommodating cavity is increased, so that an air in the second accommodating cavity enters the air storage tank through the second air outlet.

In an embodiment, the driving assembly comprises a driving part, a driving shaft and an eccentric sleeve; the driving shaft is connected with the driving part; the eccentric sleeve is sleevedly provided on the driving shaft; a distance between an axis of the driving shaft and individual points on an outer circumference of the eccentric sleeve is different; an end of the push rod away from the second accommodating cavity is sleevedly provided on the outer circumference of the eccentric sleeve; the eccentric sleeve is configured to rotate relative to the push rod; the driving part is configured to drive the driving shaft to rotate to drive the eccentric sleeve to eccentrically rotate around the axis of the driving shaft, so that the eccentric sleeve rotates relative to the push rod to drive the push rod sleeved on the outer circumference of the eccentric sleeve to move along the first direction or the second direction.

In an embodiment, the eccentric sleeve comprises a plurality of eccentric sleeves; the push rod comprises a plurality of push rods; the first housing comprises a plurality of first housings; the plurality of eccentric sleeves are sleevedly provided spaced apart on the driving shaft; the plurality of eccentric sleeves, the plurality of push rods, and the plurality of first housings are in one-to-one correspondence.

In an embodiment, the pump further comprises a pump cover; the pump cover is provided on the first housing; the second accommodating cavity is formed by the push rod, the first housing and the pump cover; and the second air inlet and the second air outlet are provided on the pump cover.

In an embodiment, the pump further comprises a blade; the blade is connected with an end of the driving assembly close to the first air inlet; the driving assembly is further configured to drive the blade to rotate, so that the external air is sucked into the first accommodating cavity through the first air inlet, and an air in the first accommodating cavity is discharged through the first air outlet.

In an embodiment, the pump is further provided with a third air inlet spaced apart from the first air inlet; the external air is configured to pass through the third air inlet to enter the pump, and then flows out of the pump through the first air outlet to realize the heat dissipation of the pump.

In an embodiment, the air compressor further comprises a joint assembly; one end of the joint assembly is in communication with the air storage tank, and the other end of the joint assembly is in communication with an external pneumatic tool; and the joint assembly is configured to output an air in the air storage tank to the external pneumatic tool.

In an embodiment, the air compressor further comprises a second housing; the pump and the controller are arranged in the second housing; the air storage tank is connected with the second housing; the second housing is provided with a fourth air inlet and a third air outlet; the external air is configured to enter the second housing through the fourth air inlet, and then pass through the first air inlet to enter the first housing; an air in the first housing is configured to flow out of the first housing through the first air outlet, and then flow out of the second housing through the third air outlet.

In an embodiment, the air compressor further comprises a windshield assembly, and the windshield assembly is arranged on a side of the fourth air inlet close to the first air inlet to surround and cover the first air inlet, so as to prevent an air discharged from the first housing through the first air outlet from entering the first housing through the first air inlet.

Compared to the prior art, the present disclosure has the following beneficial effects.

In the air compressor provided herein, the pump is controlled by a controller to pump the external air into the air storage tank. The external air can enter the pump through the first air inlet, and then flow out of the pump through the first air outlet to realize the heat dissipation of the pump. In this disclosure, the controller is arranged at the first air inlet, so that when the external air enters the pump through the first air inlet, the heat dissipation of the controller is performed at the same time, which accelerates the cooling of the controller, facilitating prolonging the working time of the controller.

### BRIEF DESCRIPTION OF THE DRAWINGS

In order to clearly explain the technical solutions in the embodiments of the present application or the prior art, the drawings that need to be used in the description of the embodiments or the prior art are briefly described below. Obviously, illustrated in the drawings are merely some embodiments of the present application. For those of ordinary skill in the art, other drawings can be obtained based on these drawings without paying creative effort.

FIG. 1 is an axonometrical drawing of an air compressor (a second housing is not shown) according to an embodiment of the disclosure;

FIG. 2 is a cross-sectional view of a pump according to an embodiment of the disclosure;

FIG. 3 is an axonometrical drawing of the pump according to an embodiment of the disclosure;

FIG. 4 is an axonometrical drawing of the air compressor according to an embodiment of the disclosure;

FIG. 5 is an axonometrical drawing of a joint assembly according to an embodiment of the disclosure;

FIG. 6 is a structural diagram of the second housing according to an embodiment of the disclosure;

FIG. 7 is an another axonometrical drawing of the air compressor according to an embodiment of the disclosure; and

FIG. 8 is a structural diagram of the air compressor (the second housing is shown) according to an embodiment of the disclosure.

In the drawings: 100: controller; 200: pump; 210: first housing; 211: first air inlet; 212: first air outlet; 213: first accommodating cavity; 214: second accommodating cavity; 220: driving assembly; 221: driving part; 222: driving shaft; 223: eccentric sleeve; 230: push rod; 240: first bearing; 250: blade cover; 251: first opening; 260: net structure; 270: pump cover; 271: second air inlet; 272: second air outlet; 280: second bearing; 290: first blade; 2100: third air inlet; 2110: second blade; 300: air storage tank; 310: exhaust valve; 400: air pipe; 500: muffler; 510: second opening; 600: joint assembly; 610: pressure-regulating valve body; 620: first joint; 630: second joint; 640: third joint; 650: first pressure sensor; 660: second pressure sensor; 670: safety valve; 700: second housing; 710: fourth air inlet; 720: third air outlet; 730: handle; 740: power switch; 750: toggle switch; 800: windshield part; 900: battery; 1000: bottom plate; 1100: supporting part; 1200: damping part; and 1300: control panel.

The disclosure will be described in detail below with reference to the embodiments and accompanying drawings to make the objectives, functions, and advantages clearer.

### DETAILED DESCRIPTION OF EMBODIMENTS

The disclosure will be described in detail below with reference to the accompanying drawings in the embodiments of the disclosure to make the technical solutions clearer and complete. Obviously, described below are merely some embodiments of the disclosure, and are not intended to limit the disclosure. Based on the embodiments in the disclosure, for those of ordinary skill in the art, other embodiments can be obtained without paying creative effort shall fall within the scope of the present disclosure defined by the appended claims.

It should be noted that as used herein, directional indications (such as up, down, left, right, front and back) are merely intended to explain the relative position relationship and movement situation among individual components in a specific posture (as shown in the accompanying drawings). If the specific posture changes, the directional indication changes accordingly. In addition, relational terms such as “first” and “second” are merely used for description, and cannot be understood as indicating or implying their relative importance or the number of indicated technical features. Thus, the features defined with “first” and “second” may explicitly or implicitly include at least one of the features. Additionally, “and/or” in the disclosure includes three solutions. For example, A and/or B includes technical solution A, technical solution B, and a combination thereof. Additionally, technical solutions of various embodiments can be combined on the premise that the combined technical solution can be implemented by those skilled in the art. When the combination of technical solutions is contradictory or cannot be implemented, it should be considered that such a combination of technical solutions does not exist, nor does it fall within the scope of the present disclosure.

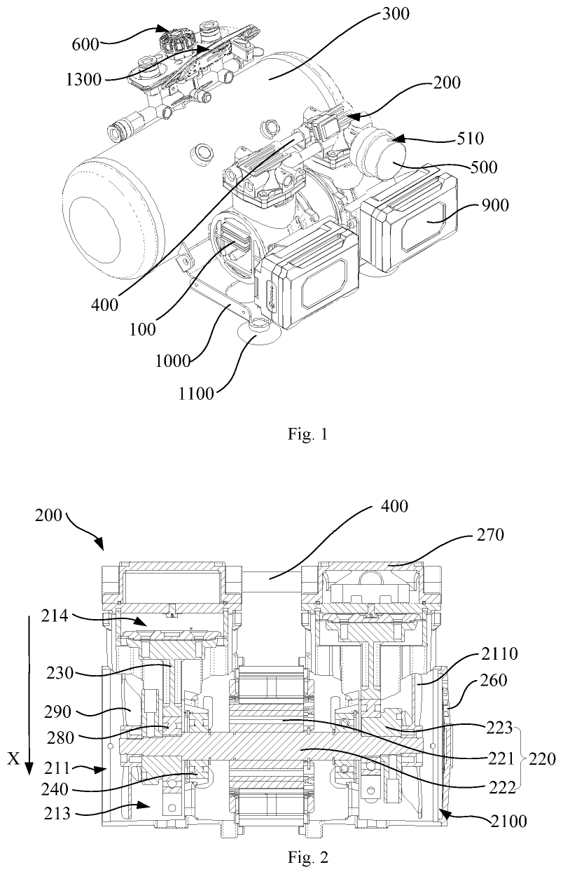

The specific structure of the air compressor will be described in detail below. As shown in FIGS. 1 and 2, an air compressor includes a controller 100, a pump 200, and an air storage tank 300. The pump 200 is in communication with the air storage tank 300. A first air inlet 211 and a first air outlet 212 are provided on the pump 200. And the pump 200 is configured to pump an external air into the air storage tank 300. And the controller 100 is provided at the first air inlet 211 of the pump 200, and is electrically connected with the pump 200. The controller 100 is configured to control an operation of the pump 200. The external air is in contact with the controller 100, and enters the pump 200 through the first air inlet 211 and then flows out of the pump 200 through the first air outlet 212, so as to realize a heat dissipation of the pump 200 and the controller 100.

The pump 200 is controlled by the controller 100 to draw the external air into the air storage tank 300. In addition, the external air can enter the pump 200 through the first air inlet 211, and then flow out of the pump 200 through the first air outlet 212, so as to realize the heat dissipation of the pump 200 and the controller 100. In this application, considering that the controller 100 is arranged at the first air inlet 211, when the external air enters the pump 200 through the first air inlet 211, the heat dissipation of the controller 100 is performed at the same time, which accelerates the cooling of the controller 100, facilitating prolonging the working time of the controller 100.

As shown in FIG. 2, the pump 200 includes a first housing 210, a driving assembly 220, and a push rod 230. The push rod 230 is arranged in the first housing 210, and divides an interior of the first housing 210 into a first accommodating cavity 213 and a second accommodating cavity 214. The driving assembly 220 is arranged in the first accommodating cavity 213, and is connected with the push rod 230. The controller 100 is electrically connected with the driving assembly 220. The controller 100 is configured to control the driving assembly 220 to drive the push rod 230 to move along a first direction or along a second direction opposite to the first direction. A side wall of the first housing 210 is provided with the first air inlet 211 and the first air outlet 212, and the first air inlet 211 and the first air outlet 212 are in communication with the first accommodating cavity 213, and the external air is in contact with the controller 100 and passes through the first air inlet 211 to enter the first accommodating cavity 213, and then flows out of the first accommodating cavity 213 through the first air outlet 212, so as to realize heat dissipation of the driving assembly 220 and the controller 100. The first housing 210 is further provided with a second air inlet 271 and a second air outlet 272. The second air inlet 271 is in communication with the second accommodating cavity 214. The second air outlet 272 is in communication with the second accommodating cavity 214 and the air storage tank 300. When the driving assembly 220 drives the push rod 230 to move along the first direction, the second accommodating cavity 214 is expanded, and an air pressure in the second accommodating cavity 214 is lowered, so that the external air is drawn to the second accommodating cavity 214 through the second air inlet 271. When the driving assembly 220 drives the push rod 230 to move along the second direction, the second accommodating cavity 214 is shrunk, and the air pressure in the second accommodating cavity 214 is increased, so that an air in the second accommodating cavity 214 enters the air storage tank 300 through the second air outlet 272. In this embodiment, the first direction is the direction indicated by the arrow on the X-axis in FIG. 4, and the second direction is opposite to the direction indicated by the arrow on the X-axis in FIG. 4.

As shown in FIGS. 1 and 2, the driving assembly 220 includes a driving part 221, a driving shaft 222 and an eccentric sleeve 223. The driving shaft 222 is connected with the driving part 221. The eccentric sleeve 223 is sleevedly provided on the driving shaft 222. A distance between an axis of the driving shaft 222 and individual points on an outer circumference of the eccentric sleeve 223 is different. An end of the push rod 230 away from the second accommodating cavity 214 is sleevedly provided on the outer circumference of the eccentric sleeve 223, and the eccentric sleeve 223 is configured to rotate relative to the push rod 230. The driving part 221 is configured to drive the driving shaft 222 to rotate to drive the eccentric sleeve 223 to eccentrically rotate around the axis of the driving shaft 222, so that the eccentric sleeve 223 rotates relative to the push rod 230 to drive the push rod 230 sleeved on the outer circumference of the eccentric sleeve 223 to move along the first direction or the second direction. In this embodiment, the eccentric sleeve 223 eccentrically rotates around the axis of the driving shaft 222 to change a distance between an upper end of the outer circumference of the eccentric sleeve 223 and the axis of the driving shaft 222, such that a distance between a position where the push rod 230 sleeved on the eccentric sleeve 223 is in contact with the upper end of the circumference of the eccentric sleeve 223 and the axis of the driving shaft 222 changes, to move the push rod 230 along the first direction or the second direction.

As shown in FIG. 2, the pump 200 further includes a first bearing 240. The first bearing 240 is sleevedly provided on the driving shaft 222, and the first bearing 240 is limitedly provided in the first accommodating cavity 213. In this embodiment, the first bearing 240 is configured to improve the rotation accuracy of the driving shaft 222 when rotating.

In an embodiment, as shown in FIG. 2, two first bearings 240 are provided, both of which are sleevedly provided on the driving shaft 222, and respectively located at both sides of the main body of the driving part 221. In this embodiment, the two first bearings 240 cooperate with each other to more reliably improve the rotation accuracy of the driving shaft 222.

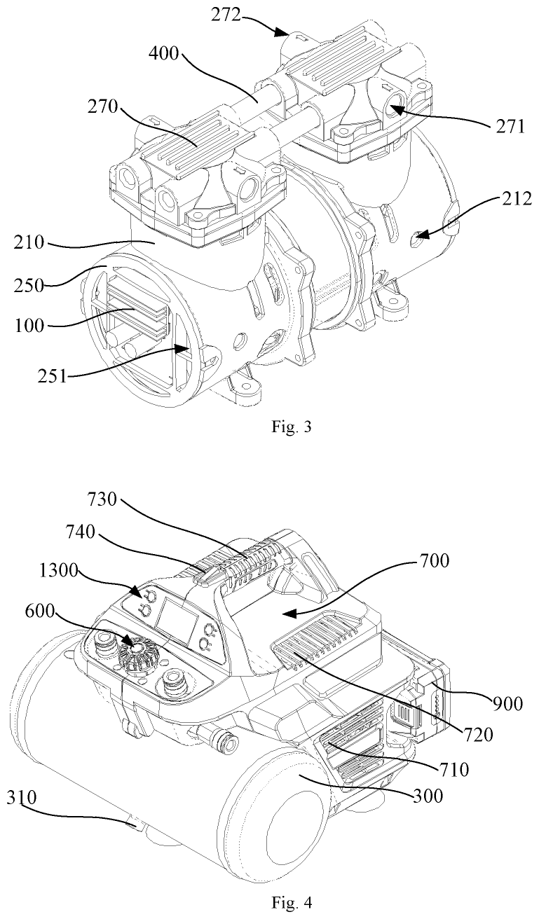

As shown in FIGS. 2 and 3, the pump 200 further includes a blade cover 250. The blade cover is arranged at the first air inlet 211, and is provided with a first opening 251, such that the external air can enter the first accommodating cavity 213 through the first opening 251. At the same time, the blade cover 250 can also block a large-size dirt from entering the first accommodating cavity 213.

In an embodiment, as shown in FIG. 3, the controller 100 is arranged on a side of the blade cover 250 away from the driving part 221, so that the controller 100 is arranged at the first air inlet 211. In this embodiment, the controller 100 is arranged on the side of the blade cover 250 away from the driving part 221, namely the controller 100 is arranged on a side of the blade cover 250 facing the external air. Such arrangement allows the external air to enter the accommodating cavity 213 through the first opening 251 and fully be in contact with the controller 100, thereby taking more heat away from the controller 100 to promote the cooling of the controller 100.

As shown in FIG. 2, the pump 200 further includes a net structure 260. The net structure 260 is arranged at the third air inlet 2100, such that the external air can enter the first accommodating cavity 213 through the net structure 260. At the same time, the net structure 260 can also block the large-size dirt from entering the first accommodating cavity 213.

In an embodiment, the eccentric sleeve includes a plurality of eccentric sleeves 223. The push rod includes a plurality of push rods 230. The first housing includes a plurality of first housings 210. The eccentric sleeves 223 are sleevedly provided spaced apart on the driving shaft 222. The eccentric sleeves 223, the push rods 230, and the first housings 210 are in one-to-one correspondence. In this embodiment, the eccentric sleeve includes two eccentric sleeves 223. The push rod includes two push rods 230. The first housing includes two first housings 210. The two eccentric sleeves 223 are sleeved spaced apart on the driving shaft 222. The two eccentric sleeves 223, two push rods 230, and two first housings 210 are in one-to-one correspondence. The driving shaft 222 drives two connecting rods to work through two eccentric sleeves at the same time, which accelerates the feeding of the external air into the air storage tank 300.

As shown in FIGS. 2 and 3, the pump 200 further includes a pump cover 270. The pump cover 270 is provided on the first housing 210. The second accommodating cavity 214 is formed by the push rod 230, the first housing 210 and the pump cover 270. The second air inlet 271 and the second air outlet 272 are provided on the pump cover 270.

In an embodiment, the pump cover 270 includes a plurality of pump covers 270, which are provided on the plurality of first housings 210 in one-to-one correspondence. In this embodiment, the pump cover 270 includes two pump covers 270, and the two pump covers 270 are provided on the two first housings 210 in one-to-one corresponding.

As shown in FIG. 2, the pump 200 further includes a second bearing 280. The eccentric sleeve 223 is sleevedly provided on the driving shaft 222 through the second bearing 280. The second bearing 280 reduces the friction between the eccentric sleeve 223 and the driving shaft 222, thereby extending the service life of the eccentric sleeve 223. Moreover, the second bearing 280 can also improve the rotation accuracy of the eccentric sleeve 223.

In an embodiment, the second bearing 280 includes a plurality of second bearings 280, and the plurality of second bearings 280 are in one-to-one correspondence with the plurality of eccentric sleeves 223. In this embodiment, the second bearing 280 includes two second bearings 280, and the two second bearings 280 are in one-to-one correspondence with two eccentric sleeves 223.

As shown in FIG. 2, the pump 200 further includes a first blade 290. The first blade 290 is connected with an end of the driving assembly 220 close to the first air inlet 211. The driving assembly 220 is further used to drive the first blade 290 to rotate, such that the external air is sucked into the first accommodating cavity 213 through the first air inlet 211 and an air in the first accommodating cavity is discharged through the first air outlet 212. In this embodiment, the first blade 290 is sleevedly provided on an end of the driving shaft 222 close to the first air inlet 211. The driving part 221 is configured to drive the driving shaft 222 to rotate, so as to drive the first blade 290 to rotate around the axis of the driving shaft 222.

As shown in FIG. 2, the pump 200 is further provided with a third air inlet 2100 spaced apart from the first air inlet 211. The external air is configured to pass through the third air inlet 2100 to enter the pump 200, and then flows out of the pump 200 through the first air outlet 212 to realize the heat dissipation of the pump 200. In this embodiment, the third air inlet 2100 and the first air inlet 211 are provided spaced apart on the first housing 210, and the third air inlet 2100 is in communication with the first accommodating cavity 213.

As shown in FIG. 2, the pump 200 further includes a second blade 2110. The second blade 2110 is connected with an end of the driving assembly 220 close to the third air inlet 2100. The driving part 221 is configured to drive the first blade 290 and the second blade 2110 to synchronously rotate to suck the external air into the first accommodating cavity 213 through the first air inlet 211 and the third air inlet 2100, followed by blowing out the air in the first accommodating cavity 213 through the first air outlet 212. In this embodiment, the second blade 2110 is sleevedly provided on an end of the driving shaft 222 close to the third air inlet 2100. The driving part 221 is configured to drive the driving shaft 222 to rotate to drive the first blade 290 and the second blade 2110 to rotate synchronously around the axis of the driving shaft 222.

As shown in FIGS. 2 and 3, the air compressor further includes an air pipe 400. The air pipe is configured to connect two pump covers 270 to realize the communication between two second accommodating cavities 214.

In an embodiment, a plurality of air pipes 400 are provided. a plurality of air pipes 400 are used to connect two pump covers 270, and are provided spaced apart. the plurality of air pipes 400 can accelerate the flowing of the air between the two second accommodating cavities 214. In this embodiment, two air pipes 400 are provided, and are provided spaced apart. Two air pipes 400 can accelerate the flowing of the air between the two second accommodating cavities 214.

In an embodiment, the pump 200 further includes a first one-way valve. The first one-way valve is arranged at the second air inlet 271, so that the external air can only enter the second accommodating cavity 214 through the second air inlet 271, and the air in the second accommodating 214 cavity cannot flow out through the second air inlet 271.

As shown FIGS. 1 and 3, the air compressor further includes a muffler 500. The muffler 500 is arranged on the pump cover 270, and is in communication with the second accommodating cavity 214. The muffler 500 is provided with a second opening 510, such that the external air can enter the muffler 500 through the second opening 510, and then enter the second accommodating cavity 214 through the second air inlet 271. The muffler 500 is configured to reduce the sound of the external air while entering the second accommodating cavity 214.

In an embodiment, the first one-way valve is arranged in the muffler 500, so that the external air can only enter the muffler 500 through the second opening 510, and then enter the second accommodating cavity 214 through the second air inlet 271. However, the air in the muffler 500 fails to be discharged to the outside through the second opening 510.

In an embodiment, the pump 200 further includes a second one-way valve. The second one-way valve is arranged at the second air outlet 272, so that the air in the second accommodating cavity 214 can only enter the air storage tank 300 through the second air outlet 272. However, the air in the air storage tank 300 fails to enter the second accommodating cavity 214 through the second air outlet 272.

As shown in FIG. 4, an exhaust valve 310 is provided on the air storage tank 300. The exhaust valve 310 is configured to discharge the air remaining in the air storage tank 300 when the air compressor stops working, so as to prevent the air storage tank 300 from exploding due to the collision. In addition, due to the long working time of the air compressor, water will be accumulated in the air storage tank 300, and can be discharged through the exhaust valve 310.

As shown in FIG. 4, the air compressor also includes a joint assembly 600. One end of the joint assembly 600 is in communication with the air storage tank 300, and the other end of the joint assembly 600 is in communication with an external pneumatic tool. The joint assembly 600 is configured to output an air in the air storage tank 300 to the external pneumatic tool.

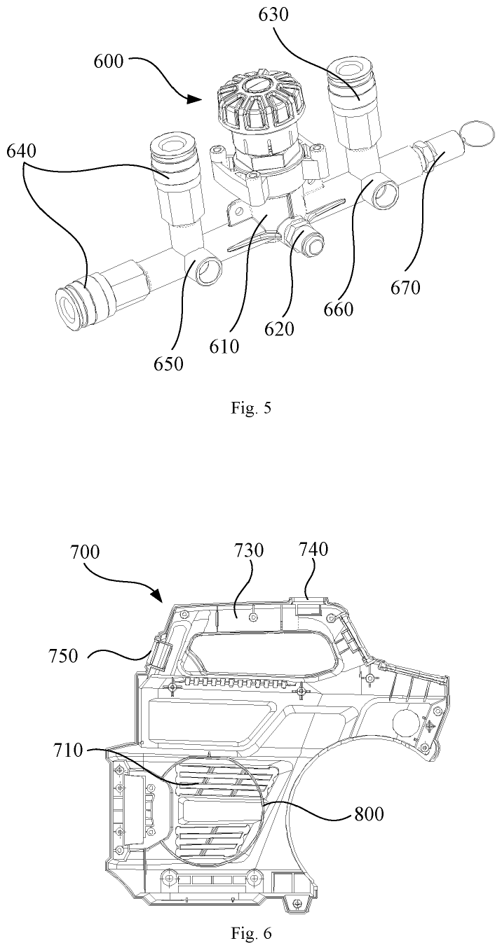

As shown in FIGS. 4 and 5, the joint assembly 600 includes a pressure-regulating valve body 610, a first joint 620, and a second joint 630. Both of the first joint 620 and the second joint 630 are connected with the pressure-regulating valve body 610, and the first joint 620 is connected with the air storage tank 300, such that an air in the air storage tank 300 can enter the pressure-regulating valve body 610 through the first joint 620, and the second joint 630 is configured to output the air entering the pressure-regulating valve body 610. In this embodiment, the second joint 630 is configured to be connected with the external pneumatic tool, and the air in the pressure-regulating valve body 610 can be output to the external pneumatic tool through the second joint 630 to drive the pneumatic tool to work.

As shown in FIG. 5, the joint assembly 600 further includes a third joint 640. The third joint 640 is connected with the pressure-regulating valve body 610. The pressure-regulating valve body 610 can adjust a pressure of the air entering the pressure-regulating valve body 610. The third joint 640 is configured to output the air whose pressure is regulated by the pressure-regulating valve body 610. The third joint 640 cooperates with the second joint 630 to realize the output of the air at different pressures, thereby outputting the air of different pressures to external pneumatic tools required to be driven by the air of different pressures.

In an embodiment, as shown in FIG. 5, the third joint 640 includes a plurality of third joints 640, which are provided spaced apart and are all connected with the pressure-regulating valve body 610. The plurality of third joints 640 output the air whose pressure is regulated by the pressure-regulating valve body 610 simultaneously, thereby driving the plurality of external pneumatic tools to work simultaneously. In this embodiment, the third joint 640 includes two third joints 640, which are provided spaced apart and are both connected with the pressure-regulating valve body 610. The two third joints 640 output the air whose pressure is regulated by the pressure-regulating valve body 610 simultaneously, thereby driving the two external pneumatic tools to work simultaneously.

As shown in FIG. 5, the joint assembly 600 further includes a first pressure sensor 650 and a second pressure sensor 660. Both of the first pressure sensor 650 and the second pressure sensor 660 are connected with the first joint 620. And both of them are electrically connected with the controller 100. The first pressure sensor 650 is configured to detect the pressure of the air in the pressure-regulating valve body 610, and the second pressure sensor 660 is configured to detect the pressure of the air in the air storage tank 300. In this embodiment, when the second pressure sensor 650 detects that the pressure of the air in the air storage tank 300 reaches to a first setting value, the pump 200 stops inputting the air into the air storage tank 300. When the first pressure sensor 650 detects that the pressure of the air in the pressure-regulating valve body 610 reaches to a second setting value, the second joint 630 outputs the air whose pressure is regulated by the pressure-regulating valve body 610 in the pressure-regulating valve body 610. The first setting value and the second setting value can be arranged according to the actual requirements.

As shown in FIG. 5, the joint assembly 600 further includes a safety valve 670. The safety valve 670 is connected with the pressure-regulating valve body 610, and is configured to release the pressure when the pressure is too high in the pressure-regulating valve body 610.

As shown in FIG. 4, the air compressor further includes a second housing 700. The pump 200 and the controller 100 are arranged in the second housing. The air storage tank 300 is connected with the second housing 700. The second housing 700 is provided with a fourth air inlet 710 and a third air outlet 720. The external air is configured to enter the second housing 700 through the fourth air inlet 710, and then pass through the first air inlet 211 to enter the first housing 210. The air in the first housing 210 is configured to flow out of the first housing 210 through the first air outlet 211, and then flow out of the second housing 700 through the third air outlet 720. In this embodiment, the external air can enter the second housing 700 through the fourth air inlet 710, followed by entering the first accommodating cavity 213 through the first air inlet 211. The air in the first accommodating cavity 213 can be discharged from the first accommodating cavity 213 through the first air outlet 212, and then discharged from the second housing 700 through the third outlet 720.

In an embodiment, the fourth air inlet 710 includes two fourth air inlets 710, and one of two fourth air inlets 710 corresponds to the first air inlet 211, and the other corresponds to the third air inlet 2100.

In an embodiment, the third air outlet 720 includes two third air outlets 720 which can accelerate the discharge of the air from the second housing 700.

In this embodiment, as shown in FIG. 4, the joint assembly 600 is connected with the second housing 700 to fix the joint assembly 600.

As shown in FIG. 6, the air compressor further includes a windshield assembly 800, which is arranged on a side of the fourth air inlet 710 close to the first air inlet 211 to surround and cover the first air inlet 211, so as to prevent an air discharged from the first housing 210 through the first air outlet 212 from entering the first housing 210 through the first air inlet 211. In this embodiment, the air discharged from the first housing 210 through the first air outlet 212 becomes the hot air, since the air takes away the heat of the controller 100 and the driving part 221. If the hot air returns to the first accommodating cavity 213 of the first housing 210 through the second air inlet 271, it is not conducive for the heat dissipation of the controller 100 and the driving part 221, in which the cold and hot air is separated by the windshield assembly 800 to prevent the hot air from being repeatedly sucked into the first accommodating cavity 213 of the first housing 210, so that the controller 100 and the driving part 221 dissipate heat fast to prolong the working time of the air compressor.

In this embodiment, the windshield assembly 800 includes two windshield assemblies 800. One windshield assembly 800 is arranged on a side of the fourth air inlet 710 close to the first air inlet 211 to surround and cover the first air inlet 211. The other windshield assembly 800 is arranged on a side of the other fourth air inlet 710 close to the third air inlet 2100 to surround and cover the third air inlet 2100.

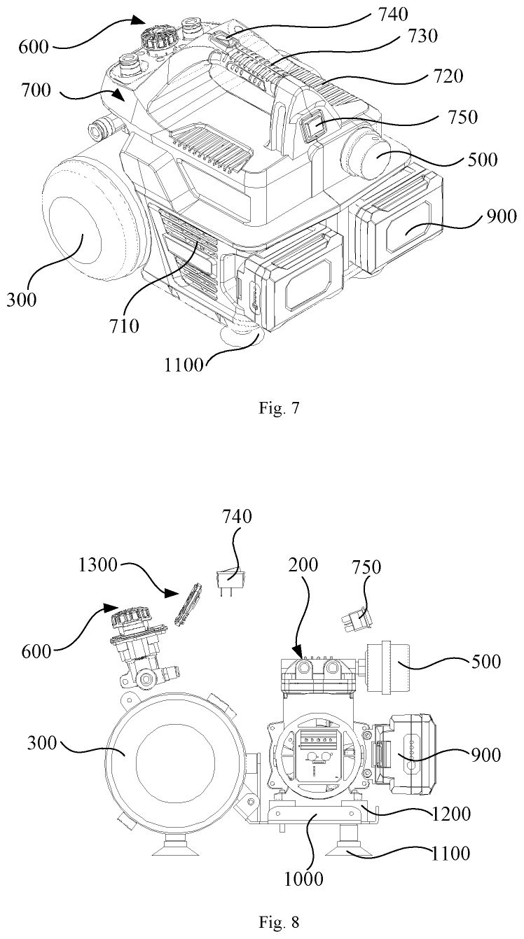

As shown in FIG. 7, the second housing 700 is provided with a handle 730, and the transfer of the air compressor is facilitated by holding the handle 730.

As shown in FIG. 7, the air compressor further includes a battery 900, which is provided on the second housing 700. The battery 900 is electrically connected with the controller 100 to supply power to the controller 100.

As shown in FIG. 7, in an embodiment, the battery 900 includes a plurality of batteries 900, which are provided spaced apart on the second housing 700. When one battery 900 is exhausted, another battery 900 can be used to continue to supply power to prolong the working time of the air compressor. In this embodiment, the battery 900 includes two batteries 900, which are provided spaced apart on the second housing 700. When one battery 900 is exhausted, another battery 900 can be used to continue to supply power to prolong the working hours of the air compressor.

As shown in FIG. 7, a power switch 740 is also provided on the second housing 700. The power switch 740 is electrically connected to the controller 100 to control the battery 900 to start or stop supplying power, thereby controlling the start and stop of the air compressor.

As shown in FIG. 7, a toggle switch 750 is also provided on the second housing 700. Both of the two batteries 900 are electrically connected with the toggle switch 750. The toggle switch 750 is configured to switch the working state of the two batteries 900. In this embodiment, when one battery 900 is exhausted, the toggle switch 750 makes the exhausted battery 900 stop supplying power to the controller 100 and another battery 900 start to supply power to the controller 100.

As shown in FIG. 8, the air compressor further includes a bottom plate 1000. The pump 200 is arranged on the bottom plate 1000, and the bottom plate 1000 is connected with the air storage tank 300 to make a more stable installation of the pump 200 and the air storage tank 300.

As shown in FIG. 8, the air compressor further includes a supporting part 1100 to support the bottom plate 1000 and the air storage tank 300.

As shown in FIG. 8, in an embodiment, the supporting part 1100 includes a plurality of supporting parts 1100. The plurality of supporting parts 1100 simultaneously support the bottom plate 1000 and the air storage tank 300, improving the support stability of the bottom plate 1000 and the air storage tank 300. In this embodiment, the supporting part 1100 includes three supporting parts 1100. One supporting part 1100 is configured to support the air storage tank 300, the other two supporting parts 1100 pass through the second housing 700 to support the bottom plate 1000. The three supporting parts 1100 are in a triangular distribution, which is more stable. As a consequence, the three supporting parts 1100 support the bottom plate 1000 and the air storage tank more stably.

As shown in FIG. 8, the air compressor further includes a damping part 1200. The damping part 1200 is arranged between the bottom plate 1000 and the pump 200 to reduce the vibration of the pump 200 during operation.

In an embodiment, the damping part includes a plurality of damping parts 1200, which are provided spaced apart between the bottom plate 1000 and the pump 200. The plurality of damping parts 1200 have a better damping effect on the pump 200. In this embodiment, the damping part includes four damping parts 1200, which are provided spaced apart between the bottom plate 1000 and the pump 200. The four damping parts have a better damping effect on the pump 200. In this embodiment, the damping part 1200 can be, but not limited to a rubber material.

As shown in FIG. 4, the air compressor further includes a control panel 1300. The control panel 1300 is connected with the second housing 700, and is electrically connected with the controller 100 to realize the control of the controller 100.

Referring to FIGS. 1-8, the processes of cooperation and action among each mechanism of the air compressor are as follows:

After the power switch 740 is turned on, the battery 900 supplies power to the controller 100, and the controller 100 controls the operation of the pump 200. In this embodiment, the controller 100 controls the driving part 221 to drive the driving shaft 222 to rotate to drive the eccentric sleeve 223 to eccentrically rotate around the axis of the driving shaft 222. The rotation of the eccentric sleeve 223 relative to the push rod 230 changes the distance between the push rod 230 and the axis of the driving shaft 222, such that the push rod moves along the first direction or the second direction. When the push rod 230 moves along the first direction, the external air can enter the second accommodating cavity 214 through the second opening 510 and the second air inlet 271. When the push rod 230 moves along the second direction, the air in the second accommodating cavity 214 can enter the air storage tank 300 through the second air outlet 272. When the second pressure sensor 660 detects that the pressure of the air in the air storage tank 300 reaches the first setting value, the pump 200 stops inputting air into the air storage tank 300, and the air whose pressure reaches the first setting value in the air storage tank 300 enters the pressure-regulating valve body 610. Then, the air in the pressure-regulating valve body 610 can be output to the external pneumatic tool through the third joint 640. The pressure-regulating valve body 610 can adjust the pressure of the air in the pressure-regulating valve body 610. When the first pressure sensor 650 detects that the pressure of the air in the pressure-regulating valve body 610 reaches the second setting value, the air in the pressure-regulating valve body 610 whose pressure is regulated by the pressure-regulating valve body 610 can be output to the external pneumatic tool through the second joint 630. The third joint 640 cooperates with the second joint 630 to output the air at different pressures.

When the driving part 221 drives the driving shaft 222 to rotate to drive the eccentric sleeve 223 to rotate eccentrically around the axis of the driving shaft 222, the driving shaft 222 also simultaneously drives the first blade 290 and the second blade 2110 to rotate synchronously, such that the external air enters the second housing 700 through the second air inlet 271, followed by contacting with the controller 100 and entering the first accommodating cavity 213 through the second air inlet 271 and the second air inlet 271. The external air sucked into the first accommodating cavity is in contact with the driving part 221 to take away the heat generated by the controller 100 and the driving part 221, and is discharged from the first accommodating cavity 213 through the first air outlet 212, then discharged from the second housing 700 through second air outlet 272, which realizes the cooling of the controller 100 and the driving part 221, and taking away the heat generated by the controller 100 and the driving part 221 when the air compressor is in use, thereby accelerating the cooling of the controller 100 and the driving part 221, and prolonging the working time of the controller 100 and the driving part 221.

Described above are merely preferred embodiments of the disclosure, which are not intended to limit the scope of the application. It should be understood that any replacements, modifications and changes made by those skilled in the art without departing from the spirit of the application shall fall within the scope of the present application defined by the appended claims.

What is claimed is:

1. An air compressor, comprising:
an air storage tank;
a pump; and
a controller;
wherein the pump is in communication with the air storage tank; a first air inlet and a first air outlet are provided on the pump; and the pump is configured to pump an external air into the air storage tank; and
the controller is provided at the first air inlet of the pump, and is electrically connected with the pump; the controller is configured to control an operation of the pump; the external air is in contact with the controller, and enters the pump through the first air inlet and then flows out of the pump through the first air outlet, so as to realize a heat dissipation of the pump and the controller.

2. The air compressor of claim 1, wherein the pump comprises a first housing, a driving assembly and a push rod; the push rod is arranged in the first housing, and divides an interior of the first housing into a first accommodating cavity and a second accommodating cavity; the driving assembly is arranged in the first accommodating cavity, and is connected with the push rod; the controller is electrically connected with the driving assembly; the controller is configured to control the driving assembly to drive the push rod to move along a first direction or along a second direction opposite to the first direction; a side wall of the first housing is provided with the first air inlet and the first air outlet, and the first air inlet and the first air outlet are in communication with the first accommodating cavity; the external air is in contact with the controller and passes through the first air inlet to enter the first accommodating cavity, and then flows out of the first accommodating cavity through the first air outlet, so as to realize heat dissipation of the driving assembly and the controller; the first housing is further provided with a second air inlet and a second air outlet; the second air inlet is in communication with the second accommodating cavity; the second air outlet is in communication with the second accommodating cavity and the air storage tank; when the driving assembly drives the push rod to move along the first direction, the second accommodating cavity is expanded, and an air pressure in the second accommodating cavity is lowered, so that the external air is drawn to the second accommodating cavity through the second air inlet; when the driving assembly drives the push rod to move along the second direction, the second accommodating cavity is shrunk, and the air pressure in the second accommodating cavity is increased, so that an air in the second accommodating cavity enters the air storage tank through the second air outlet.

3. The air compressor of claim 2, wherein the driving assembly comprises a driving part, a driving shaft and an eccentric sleeve; the driving shaft is connected with the driving part; the eccentric sleeve is sleevedly provided on the driving shaft; a distance between an axis of the driving shaft and individual points on an outer circumference of the eccentric sleeve is different; an end of the push rod away from the second accommodating cavity is sleevedly provided on the outer circumference of the eccentric sleeve; the eccentric sleeve is configured to rotate relative to the push rod; the driving part is configured to drive the driving shaft to rotate to drive the eccentric sleeve to eccentrically rotate around the axis of the driving shaft, so that the eccentric sleeve rotates relative to the push rod to drive the push rod sleeved on the outer circumference of the eccentric sleeve to move along the first direction or the second direction.

4. The air compressor of claim 3, wherein the eccentric sleeve comprises a plurality of eccentric sleeves; the push rod comprises a plurality of push rods; the first housing comprises a plurality of first housings; the plurality of eccentric sleeves are sleevedly provided spaced apart on the driving shaft; the plurality of eccentric sleeves, the plurality of push rods, and the plurality of first housings are in one-to-one correspondence.

5. The air compressor of claim 2, wherein the pump further comprises a pump cover; the pump cover is provided on the first housing; the second accommodating cavity is formed by the push rod, the first housing and the pump cover; and the second air inlet and the second air outlet are provided on the pump cover.

6. The air compressor of claim 2, wherein the pump further comprises a blade; the blade is connected with an end of the driving assembly close to the first air inlet; the driving assembly is further configured to drive the blade to rotate, so that the external air is sucked into the first accommodating cavity through the first air inlet, and an air in the first accommodating cavity is discharged through the first air outlet.

7. The air compressor of claim 1, wherein the pump is further provided with a second air inlet spaced apart from the first air inlet; the external air is configured to pass through the second air inlet to enter the pump, and then flows out of the pump through the first air outlet to realize the heat dissipation of the pump.

8. The air compressor of claim 1, wherein the air compressor further comprises a joint assembly; one end of the joint assembly is in communication with the air storage tank, and the other end of the joint assembly is in communication with an external pneumatic tool; and the joint assembly is configured to output an air in the air storage tank to the external pneumatic tool.

9. The air compressor of claim 1, wherein the air compressor further comprises a second housing; the pump and the controller are arranged in the second housing; the air storage tank is connected with the second housing; the second housing is provided with a second air inlet and a second air outlet; the external air is configured to enter the second housing through the second air inlet, and then pass through the first air inlet to enter the first housing; an air in the first housing is configured to flow out of the first housing through the first air outlet, and then flow out of the second housing through the second air outlet.

10. The air compressor of claim 9, wherein the air compressor further comprises a windshield assembly, and the windshield assembly is arranged on a side of the second air inlet close to the first air inlet, to surround and cover the first air inlet, so as to prevent an air discharged from the first housing through the first air outlet from entering the first housing through the first air inlet.
